(19) United States
(12) Patent Application Publication
(10) Pub. No.: US 2006/0138650 A1
(43) Pub. Date: Jun. 29, 2006

(54) Integrated circuit packaging device and method for matching impedance

(75) Inventors: Fernando N. Hidalgo, Ashburn, VA (US); Phuong T. Huynh, Annandale, VA (US); John W. McCorkle, Vienna, VA (US)

Correspondence Address: POSZ LAW GROUP, PLC, 12040 SOUTH LAKES DRIVE, SUITE 101, RESTON, VA, 20191, US

(73) Assignee: FREESCALE SEMICONDUCTOR, INC.

(21) Appl. No.: 11/022,813

(22) Filed: Dec. 28, 2004

(51) Int. Cl. H01L 23/52

(52) U.S. Cl. 257/728; 257/691; 257/693

(57) ABSTRACT

An integrated circuit device is provided. The integrated circuit includes an integrated circuit chip (110) having a chip input/output element (240); a packaging component (220) having a package input/output element (270); two or more connection elements (260) for connecting the chip input/output element with the package input/output element; and a protective layer (290) covering the integrated circuit chip, the two or more connection elements, and a portion of the packaging such that the package input/output element is uncovered. The two or more connection elements are configured to provide a set input/output impedance at the package input/output element. This is accomplished by considering the inductive and capacitive properties of each connection element, and selecting an appropriate number and orientation for the one or more connection elements.

### FIELD OF THE INVENTION

The present invention relates in general to integrated circuit devices, including those used for ultra wideband (UWB) systems. In particular the present invention can be applied to integrated circuit devices including low noise amplifiers used in UWB systems. A particular aspect of the present invention relates to the impedance matching of input/output nodes for integrated circuit devices using the properties of the integrated circuit packaging. Another aspect of the present invention relates to the use of multiple connection elements between the pads of an integrated circuit chip and an integrated circuit package to match input/output impedance.

### BACKGROUND OF THE INVENTION

When an integrated circuit (IC) device is formed, it will have an inherent impedance associated with each of its input/output nodes. This impedance will vary depending upon the properties of the internal circuitry connected to that node.

In many circuits it is desirable to match these impedances with a desired value. For example, to maximize power transfer between various elements in a circuit it is desirable to make certain that all of the elements have the same input/output impedance. For wireless transceiver elements it is generally desirable to match all of the elements in a receiver or transmitter to the impedance of the antenna. Typically this value is 50 or 75 ohms.

In narrowband wireless transceivers the circuits used to match impedance are generally designed such that they function properly over the narrow frequency band that they are transmitting in. Typically this is in the range of 10 to 50 MHz, though larger and smaller bands can be used as well. The bandwidth may be partitioned into channels. For example, a 100 MHz spectrum may be allocated and divided into 10 channels of 10 MHz each, all of which can be used independently of the others.

Typically narrowband matching is accomplished via a simple conjugate matching network. This can be as simple as an inductor if the circuit input impedance is capacitive, or alternatively a capacitor if the circuit input impedance is inductive. The point of the matching is to resonate the L-C network at a given frequency and thus obtain a desired impedance level.

However, this requires additional circuitry to accomplish. And as a result, the size and complexity of electronic devices that require impedance matching are increased. Furthermore, such implementations are not desirable in UWB venues since their impedance matching breaks down over the large frequency ranges (generally in excess of hundreds of MHz).

Therefore it would be desirable to provide an impedance matching circuit that would be functional over larger frequency ranges, and which would take up a smaller amount of space.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages in accordance with the present invention.

FIG. 1 a block diagram of an integrated circuit device with external impedance matching circuits;

FIG. 2 is a diagram of the integrated circuit device including an integrated circuit chip and attached integrated circuit packaging of FIG. 1;

FIG. 3 is a cross-sectional view of the integrated circuit device and attached integrated circuit packaging of FIG. 2;

FIG. 4 is a cross-sectional view of an integrated circuit device and attached integrated circuit according to an alternate embodiment;

FIG. 5 is a block diagram of an integrated circuit device with internal impedance matching circuits;

FIG. 6 is a diagram of the integrated circuit device and attached integrated circuit packaging of FIG. 5;

FIG. 7 is a circuit diagram of an equivalent circuit for a twin wire bond connection of FIG. 6; and

FIG. 8 is a cross-sectional view of an integrated circuit device and attached integrated circuit according to an alternate embodiment.

### DETAILED DESCRIPTION OF PREFERRED EMBODIMENTS

As noted above, it is generally desirable in electronic devices to match the impedances of devices connected together, and to keep those matched impedances low. In a wireless receiver or transmitter, it is particularly desirable to keep all of the devices in the signal processing chain at the same input/output impedance as the antenna, which is typically 50 or 75 ohms.

Impedance matching, in general, is obtained by first understanding the intrinsic impedance properties of a circuit on which one desires to obtain a desired impedance level (e.g., 50 ohms). In designing most circuits (such as a low noise amplifier), it is not possible to directly obtain the desired impedance throughout the frequency band of interest. The challenge becomes finding mechanisms by which a desired impedance level is obtained over a desired frequency bandwidth.

Impedance matching makes use of components external to a circuit that work in tandem with the intrinsic impedance properties of the circuit to ultimately produce the desired impedance level. Generally speaking, these external components are inductors, capacitors, resistors, and transmission line elements. The latter are electrical elements which have an established impedance level, such as 50 ohms.

External Impedance Matching

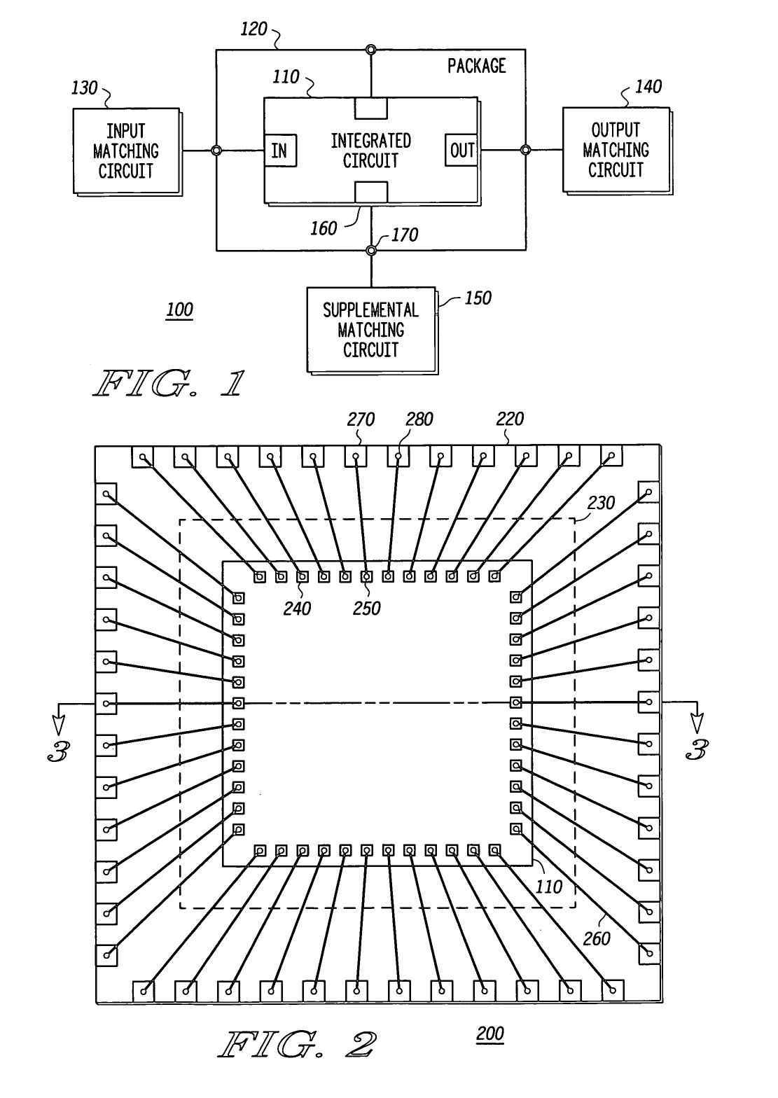

One way of matching the impedances of an integrated circuit device is to use external impedance matching. In this implementation, external circuitry is provided at the input and output nodes of an integrated circuit package to match its input/output impedance to a desired value. FIG. 1 a block diagram of an integrated circuit device with external impedance matching circuits.

As shown in FIG. 1, the integrated circuit device 100 includes an integrated circuit (IC) chip 110, an IC package 120, an input matching circuit 130, and an output matching circuit 140. It may also include one or more supplemental matching circuits 150. The IC chip 110 includes a plurality of chip input/output pads 160, while the IC package 120 includes a plurality of package input/output pads 170. A plurality of connection elements 180 connect the chip input/output pads 160 with the package input/output pads 170.

The IC chip 110 is a semiconductor device containing internal circuitry. It may contain a single simple circuit element, multiple complex circuit elements, or a mix of different types of circuit elements. In one particular implementation the IC chip 110 includes a low noise amplifier (LNA) used in a UWB device.

Although the IC chip 110 in FIG. 1 is shown as having only four chip input/output pads 160, this is by way of example only. Alternate embodiments can have larger or smaller numbers of input/output pads 160.

The IC package 120 includes elements used to hold and protect the IC chip, and to allow it to function with external circuit elements. It can include an IC substrate, a protective layer, and a plurality of package input/output pads 170. In some embodiments the IC chip 110 can be attached on top of an IC substrate, while in others it can be embedded within an IC substrate. However, various alternative IC package 120 designs are possible.

The chip input/output pads 160 can be any desired element used to provide electrical connections to circuitry on the IC chip 110. Some of these chip input/output pads 160 will be connected to the inputs of circuit elements on the IC chip 110; other chip input/output pads 160 will be connected to the outputs of circuit elements on the IC chip 110; other chip input/output pads 160 may be connected to intermediate nodes of circuit elements on the IC chip 110. The chip input/output pads 160 may be a simple metallic contact surfaces, structures comprising ESD diodes, fuses, or embedded logic, or may be any other suitable element.

The package input/output pads 170 can be any desired element used to provide electrical connections from the IC package 120 to elements outside the IC package 120. The package input/output pads 170 may be lead frames, solder balls (i.e., bumps), or any other suitable element.

The connection elements 180 are used to electrically connect the chip input/output pads 160 to the package input/output pads 170. The connection elements 180 may be wire bonds, conductive vias through an IC substrate, or any other suitable element.

The input matching circuit 130 is connected to a package input/output pad 170 that corresponds to an input for a circuit formed in the IC chip 110. It operates to render the effective input impedance of the circuit element to be a desired value. This desired value can be any desired input impedance, but is often in the range of 20-100 ohms. Because many circuits require an input impedance of about 50 ohms or about 75 ohms, many implementations of the input matching circuit 130 will use one of these values as its desired input impedance value.

The input matching circuit 130 may comprise an inductive element and a capacitive element (as well as a resistive element if the circuit design allows it) formed to match the impedance in a way understood by one skilled in the art of circuit design

The output matching circuit 140 is connected to a package input/output pad 170 that corresponds to an output for a circuit formed in the IC chip 110. It operates to render the effective output impedance of the circuit element to be a desired value. As with the input matching circuit 130, this desired value can be any desired input impedance, but is often in the range of 20-100 ohms. Because many circuits require an output impedance of about 50 ohms or about 75 ohms, many implementations of the output matching circuit 140 will use one of these values as its desired output impedance value.

The output matching circuit 140 may comprise an inductive element and a capacitive element (as well as a resistive element if the circuit design allows it) formed to match the impedance in a way understood by one skilled in the art of circuit design

The supplemental matching circuits 150 is connected to a package input/output pad 170 that corresponds to an intermediate portion of a circuit formed in the IC chip 110. It typically operates in conjunction with the input matching circuit 130 to render the effective input impedance of the circuit element to be a desired value.

The supplemental matching circuit 150 may comprise an inductive element and a capacitive element (as well as a resistive element if the circuit design allows it) formed to match the impedance in a way understood by one skilled in the art of circuit design.

When used in a UWB device, it is necessary that each of the input matching circuits 130 (with any supplemental matching circuits 150) and output matching circuits 140 operate to provide the same effective impedance over the entire range of frequencies of the UWB device. The matching circuits can be placed on a PC board as discrete elements.

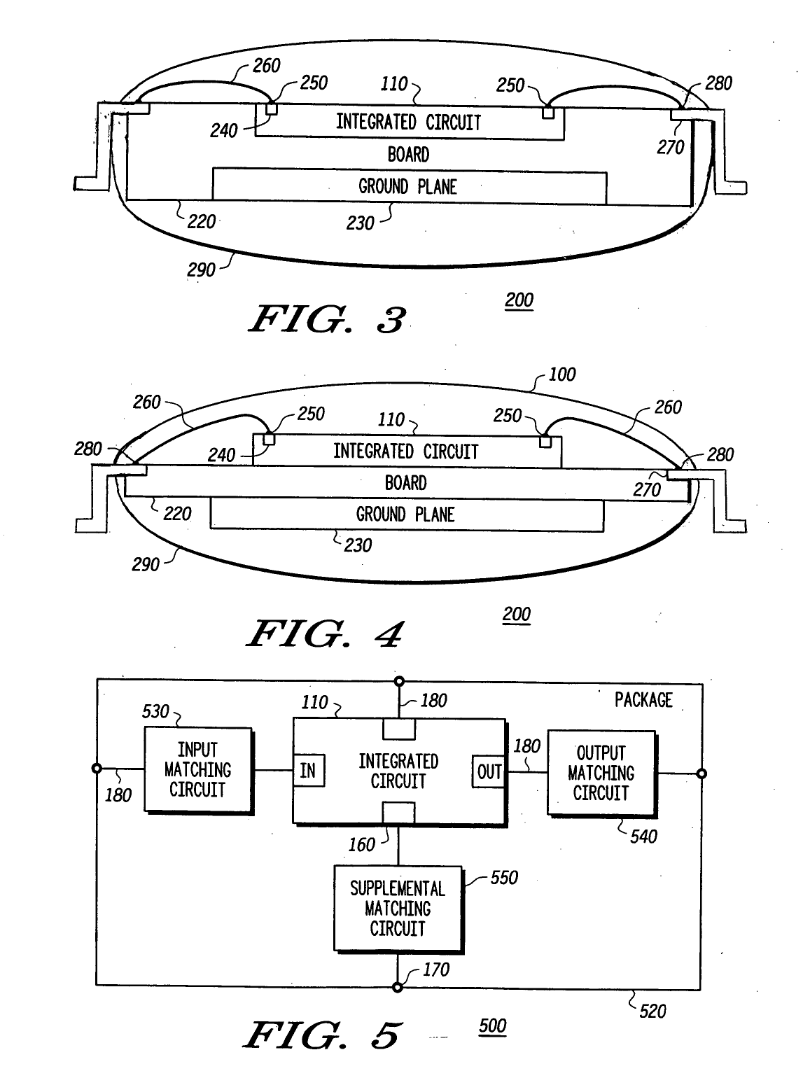

FIG. 2 is a diagram of the integrated circuit device including an integrated circuit chip and attached integrated circuit packaging of FIG. 1. FIG. 3 is a cross-sectional view of the integrated circuit device and attached integrated circuit packaging of FIG. 2.

As shown in FIGS. 2 and 3, the IC device 200 includes an IC chip 10, an IC package substrate 220, and a ground plane 230. The IC chip 10 includes a plurality of die pads 240, while the IC package substrate 220 includes a plurality of package pads 270. A plurality of wire bonds 260 connect the die pads 240 to the package pads 270. The wire bonds 260 are attached to the die pads 240 and package pads 270 by connection elements 250, 280. An insulating layer 290 is then formed over the IC chip 110, wire bonds 260, and ground plane 230.

The IC package substrate 220 is a conventional IC package substrate, having the IC chip 10 and the ground plane 230 embedded in it. The IC package substrate 220 is made of an electrically insulating material to isolate various components in the IC device 200. The plurality of package pads 270 are provided on the IC package substrate 220 to provide electrical connections between the package and external devices. In some embodiments these pads 270 will be formed in straight rows, while in others they can be formed in parallel staggered rows.

The IC chip 10 is a semiconductor chip having electronic circuitry formed in it. In one particular embodiment, this circuitry can include a low noise amplifier (LNA). The circuitry in the IC chip 110 is electrically connected to external elements through the plurality of die pads 240.

In particular, individual die pads 240 are connected to individual package pads 270 by wire bonds 260, one wire bond connecting a die pad 240 and package pad 270 pair. The wire bonds 260 can be connected to the die pad 240 and the package pad 270 by solder 250, 280, or any other suitable connection mechanism. If wire bonds are used, they can be soldered directly to the surface of the pads 240, 270.

The ground plane 230 provides an electrical ground for the IC chip 110, and is insulated from the IC chip 110 by the IC package substrate 220.

The entire IC chip 10, ground plane 230, and wire bonds 260 are then covered by an insulating layer 290 such as a ceramic or a plastic to both protect the circuitry from harm and to insulate it from interference from other devices.

FIG. 4 is a cross-sectional view of an integrated circuit device and attached integrated circuit according to an alternate embodiment. As shown in FIG. 4, this embodiment is similar to the embodiment of FIG. 3, except that it has an IC chip 110 and a ground plane 230 affixed to the surface of an IC package substrate 220, rather than being formed integral with the IC package substrate 220. Aside from this change, the descriptions above with respect to FIGS. 2 and 3 above apply to the embodiment of FIG. 3.

However, as noted above, this IC device 200 shown in FIGS. 2 and 4 will not necessarily have a uniform input/output impedance at each package pad 270. In order to provide a uniform input/output impedance at each relevant package pad 270 it will be necessary to have an external matching circuit attached to any package pad 270 that needs to meet those requirements. Generally in a standard IC device, not all of the pins will need to have impedance matching circuits, so these matching circuits will only be required on a subset of the total output pins.

Such external matching circuits will comprise capacitive, inductive, and resistive elements and will increase the size and complexity of any resulting electronic device that incorporates the IC device 200.

Internal Impedance Matching

One way to simplify an integrated circuit device that requires impedance matching is to use the properties of its packaging to provide the necessary impedance matching. FIG. 5 is a block diagram of an integrated circuit device with internal impedance matching circuits.

As shown in FIG. 5, the integrated circuit device 500 includes an integrated circuit (IC) chip 110, an IC package 520, an input matching circuit 530, and an output matching circuit 540. It may also include one or more supplemental matching circuits 550. The IC chip 110 includes a plurality of chip input/output pads 160, while the IC package 520 includes a plurality of package input/output pads 170. One or more connection elements 180 connect the chip input/output pads 160 with the package input/output pads 170 in cases where no impedance matching is requited. For chip input/output pads 160 and package input/output pads 170 pairs that require impedance matching, the various matching circuits 530, 540, and 550 serve to connect the chip input/output pads 160 to the associated package input/output pad 170. In this case there may or may not be separate connection elements 180. The matching circuits 530, 540, and 550 may serve as the entire connectors between the pads 160 and 170, or they may have a connection element 180 connecting them to the IC pad 160, the package pad 170, or both.

The IC chip 110 is a semiconductor device containing internal circuitry, as described above with respect to FIG. 1. Both the IC chip 110 and the chip input/output pads 160 function as described above.

The IC package 520 includes elements used to hold and protect the IC chip 110, and to allow it to function with external circuit elements. It can include an IC package substrate, a protective layer, and a plurality of package input/output pads 170. In some embodiments the IC chip 110 can be attached on top of an IC package substrate, while in others it can be embedded within an IC package substrate. However, various alternative IC package 520 designs are possible.

The package input/output pads 170 can be any desired element used to provide electrical connections from the IC package 120 to elements outside the IC package 120. They are analogous to the package input/output pads 170 described with reference to FIG. 1. As such they can be may be lead frames, solder balls (i.e., bumps), or any other suitable element.

The connection elements 180 are used to electrically connect chip input/output pads 160 to the package input/output pads 170 in situations where the input/output impedance for the input/output pad 170 does not need to be matched. As noted above with respect to FIG. 1, the connection elements 180 may be wire bonds, conductive vias through an IC package substrate, or any other suitable element.

The input matching circuit 530 is formed by a part of the IC device 500 that is connected between the chip input/output pad 160 and the package input/output pad 170 that corresponds to an input for a circuit formed in the IC chip 110. It operates to render the effective input impedance of the circuit element to be a desired value. This desired value can be any desired input impedance, but is often in the range of 20-100 ohms. Because many circuits require an input impedance of about 50 ohms or about 75 ohms, many implementations of the input matching circuit 530 will use one of these values as its desired input impedance value.

The input matching circuit 530 may comprise an inductive element and a capacitive element (as well as a resistive element if the circuit design allows it) formed to match the impedance in a way understood by one skilled in the art of circuit design. In the embodiment disclosed in FIG. 5, the input matching circuit 530 is two or more wire bonds connected between a single chip input/output pad 160 and package input/output pad 170 pair.

The output matching circuit 540 is formed by a part of the IC device 500 that is connected between the chip input/output pad 160 and the package input/output pad 170 that corresponds to an output for a circuit formed in the IC chip 110. It operates to render the effective output impedance of the circuit element to be a desired value. As with the input matching circuit 530, this desired value can be any desired input impedance, but is often in the range of 20-100 ohms. Because many circuits require an output impedance of about 50 ohms or about 75 ohms, many implementations of the output matching circuit 540 will use one of these values as its desired output impedance value.

The output matching circuit 540 may comprise an inductive element and a capacitive element (as well as a resistive element if the circuit design allows it) formed to match the impedance in a way understood by one skilled in the art of circuit design. In the embodiment disclosed in FIG. 5, the output matching circuit 540 is two or more wire bonds connected between a single chip input/output pad 160 and package input/output pad 170 pair.

The supplemental matching circuits 550 is formed by a part of the IC device 500 that is connected between the chip input/output pad 160 and the package input/output pad 170 that corresponds to an intermediate portion of a circuit formed in the IC chip 110. It typically operates in conjunction with the input matching circuit 530 to render the effective input impedance of the circuit element to be a desired value. As with the input and output matching circuits 530 and 540, this desired value can be any desired input impedance, but is often in the range of 20-100 ohms. Because many circuits require an output impedance of about 50 ohms or about 75 ohms, many implementations of the supplemental matching circuit 550 will use one of these values as its desired supplemental impedance value.

The supplemental matching circuit 550 may comprise an inductive element and a capacitive element (as well as a resistive element if the circuit design allows it) formed to match the impedance in a way understood by one skilled in the art of circuit design. In the embodiment disclosed in FIG. 5, the supplemental matching circuit 550 is two or more wire bonds connected between a single chip input/output pad 160 and package input/output pad 170 pair.

When used in a UWB device, it is necessary that each of the input matching circuits 530, output matching circuits 540, and supplemental matching circuits 550 operate to provide the same effective impedance over the entire range of frequencies of the UWB device. This can be accomplished by arranging the wire bonds in conjunction with the package physical structure (e.g., ground plane and physical characteristics) as well as accounting for interactions with the IC circuitry.

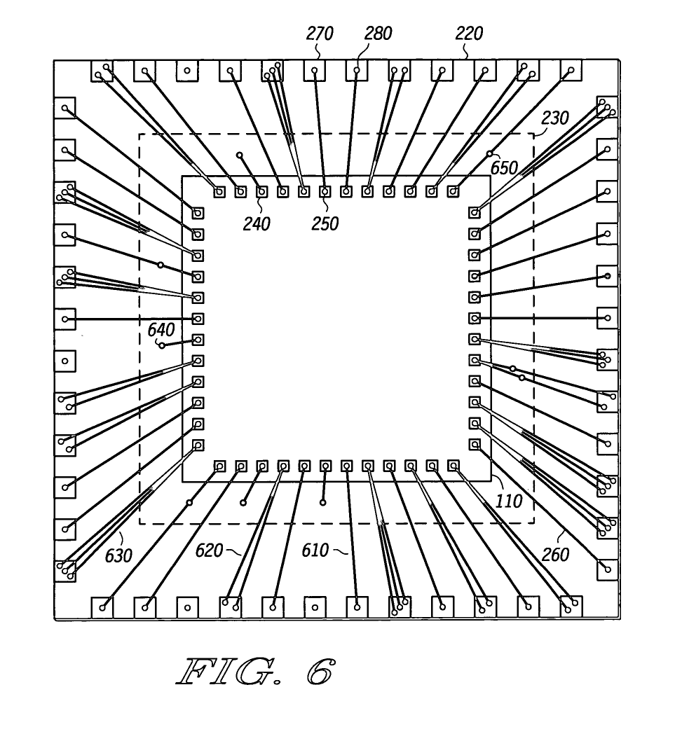

FIG. 6 is a diagram of the integrated circuit device and attached integrated circuit packaging of FIG. 5. As shown in FIG. 6, the IC device 600 includes an IC chip 110, an IC package substrate 220, and a ground plane 230. The IC chip 110 includes a plurality of die pads 240, while the IC package substrate 220 includes a plurality of package pads 270. A plurality of wire bonds 260 connect the die pads 240 to the package pads 270. The wire bonds 260 are attached to the die pads 240 and package pads 270 by connection elements 250, 280. An insulating layer 290 is then formed over the IC chip 110, wire bonds 260, and ground plane 230.

In general, like elements of FIG. 6 behave as described above with respect to FIGS. 2 to 4. However, the connections between the die pads 240 and the package pads are arranged to provide proper impedance matching where necessary.

In particular, when impedance matching is required, two or more wire bonds are used to connect a single pair of chip input/output pad 240 and package input/output pad 270. The two parallel wire bonds form an inductive/capacitive circuit that performs the function of an impedance matching circuit.

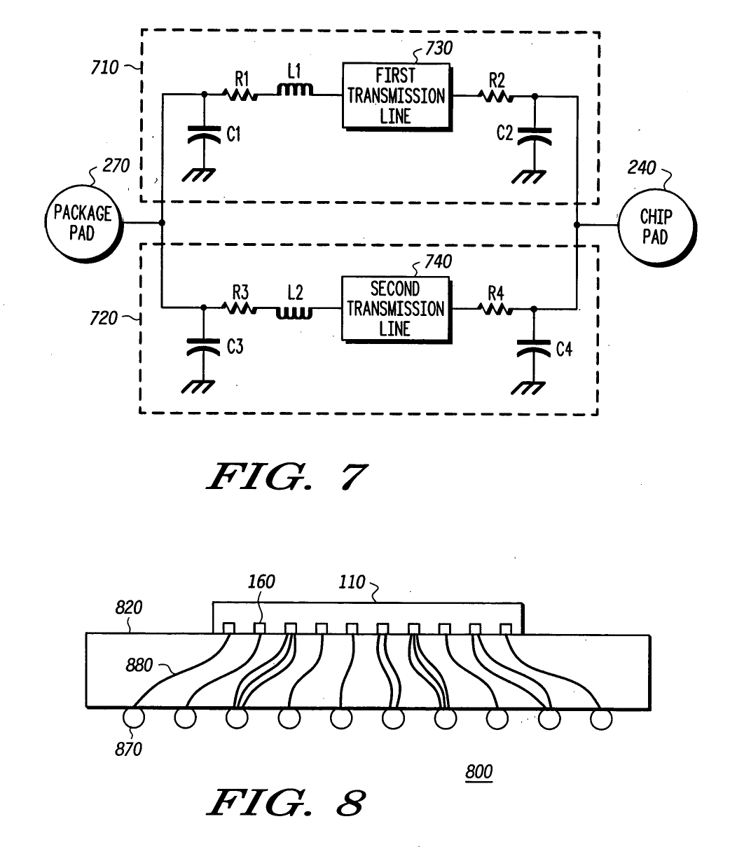

FIG. 7 is a circuit diagram of an equivalent circuit for a twin wire bond connection of FIG. 6. As shown in FIG. 7, two wire bonds 710 and 720 are formed between a chip pad 240 and a package pad 270. In their physical forms, the first and second wire bonds 710 and 720 will be wire bonds electrically connected between an IC pad 240 and a package pad 270. In most cases part of each of the wire bonds 710, 720 will be formed over a package ground plane, and part of each of the wire bonds 710, 720 will not be formed over the package ground plane.

A wire bond with a ground plane beneath it forms a distributed inductor with a distributed parasitic capacitor to ground (the capacitive properties of that portion of the wire bond with respect to the ground plane), becoming a transmission line operating at an established impedance. In addition the wire bond has a resistive component shown on both sides of the transmission line. The wire bond section that is not over the ground plane is modeled as an inductor. The connection of the bond wire to the chip pad, and the connection of the bond wire to the package pad are shown as capacitors, representing the effective parasitic capacitance of these larger elements to ground, as shown in FIG. 7.

As a result, the first wire bond 710 can be electrically represented as a first capacitor C1, a first resistor R1, a first inductor L1, a first transmission line 730, a second resistor R2 and a second capacitor C2. The first capacitor C1 represents the capacitive effect of the first wire bond 710 with respect to conductive elements on the IC (e.g., an IC ground plane). The first resistor R1 and the first inductor L1 represent the equivalent circuit of the portion of the first wire bond 710 that is not formed over a package ground. And the first transmission line 730, the second resistor R2, and the second capacitor C2 represent the equivalent circuit of the portion of the first wire bond 710 that is formed over a package ground.

Similarly, the second wire bond 720 can be electrically represented as a third capacitor C3, a third resistor R3, a second inductor L2, a second transmission line 740, a fourth resistor R4 and a fourth capacitor C4. The third capacitor C3 represents the capacitive effect of the second wire bond 720 with respect to conductive elements on the IC (e.g., an IC ground plane). The third resistor R3 and the second inductor L2 represent the equivalent circuit of the portion of the second wire bond 720 that is not formed over a package ground. And the second transmission line 740, the fourth resistor R4, and the fourth capacitor C4 represent the equivalent circuit of the portion of the second wire bond 720 that is formed over a package ground.

Although FIG. 7 discloses an equivalent circuit for a wire bond pair, it can be extended for any number of wire bonds. Each wire bond would be represented by a series of inductors, capacitors, resistors, and transmission lines, as needed. If each wire bond has the same general positioning (i.e., connected to pads, partly over a ground plane, partly not over a ground plane), then the equivalent circuits will be as shown in FIG. 7. However, if the positioning of the wire bonds changes, their equivalent circuits will change accordingly. Regardless, the capacitive and inductive properties of the wire bonds can be used to match input or output impedances.

By making use of double or triple wire bonds (or greater numbers of wire bonds), one can come closer to desired impedance levels (e.g., 50 ohms or 75 ohms). Additionally, the frequency response of two (or more) conductors in parallel is broader than the frequency response of one conductor alone. As a result, using two (or more) wire bonds in parallel has a broader frequency response, which is advantageous for UWB implementations. For example, through the use of multiple wire bonds it is possible to achieve a frequency response that provides a 50 ohm or 75 ohm input or output impedance over a bandwidth exceeding 2 GHz.

Although FIG. 6 only discloses examples in which one, two, or three wire bonds are arranged between a single pair of chip input/output pad 240 and package input/output pad 270, and FIG. 7 only discloses an equivalent circuit for a dual wire bond connection, alternate embodiments can use larger numbers of wire bonds between one chip input/output pad 240 and package input/output pad 270 pair. The number and placement can be varied to achieve the desired input/output impedance. As the desired impedance and the circuit formulation change in different embodiments, the precise number and placement of elements will change to achieve the desired impedance matching.

Furthermore, in cases where a chip input/output pad 240 must be grounded, the connecting element can be directly connected to the ground plane 230 through a via 640 in the IC package substrate 220. If the chip input/output pad 240 needs to be connected to ground but no external circuitry need reference that pad, then a short wire bond 680 can be attached from the chip input/output pad 240 to the via 640. If however, some external circuitry will need to reference that grounded chip input/output pad 240, then the chip input/output pad 240 will be connected to the via 640 and then to a package input/output pad 270 by a wire bond 690.

In alternate embodiments other sorts of connecting elements can be used besides wire bonds. For example, if a ball grid array is used for packaging, the connecting elements will be conductive vias in the IC package substrate. Equivalent circuits for these alternate embodiments will be comparable to that shown in FIG. 7, depending upon the particular positioning and structure of the connecting elements. FIG. 8 is a cross-sectional view of an integrated circuit device and attached integrated circuit according to an alternate embodiment. In this embodiment, a ball grid array is used in which vias in an IC package substrate filled with a conductive substance are used as the connection elements 180 or as the internal matching circuits 530, 540, and 550.

As shown in FIG. 8, an IC device 800 includes an IC chip 110 formed on one surface of an IC package substrate 820. The IC chip includes a plurality of chip input/output pads 160, which are connected to solder balls 870 on the opposite surface of the IC package substrate 820 by vias 880 in the IC package substrate 820.

The IC chip 110 is a semiconductor chip as described above. Its chip input/output pads 160 are formed such that they can be electrically attached to the through the vias 880, which are filled with an electrically-conductive material.

As with the wire bonds of FIGS. 5 and 6, the vias 880 of FIG. 8 can be arranged to form matching circuits. In particular, multiple vias can be set to connect the same pair of chip input/output pad 160 and solder ball 870.

The wire bonds and vias shown above in FIGS. 5 to 8 are shown by way of example. Alternate ways of forming an IC package and connecting chip input/output pads to package input/output pads can be arranged such that they provide the necessary matching circuits at device inputs and outputs. In this way, the need for external matching circuits can be eliminated and the size of a final product incorporating an IC device can be reduced.

In particular, impedance matching circuits can be created at package input/output pads by connecting the package input output pads to chip input/output pads using multiple connecting elements. These multiple connecting elements can be used to create an inductive/capacitive circuit that can be used as an impedance matching circuit.

### CONCLUSION

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled. The various circuits described above can be implemented in discrete circuits or integrated circuits, as desired by implementation.

1. An integrated circuit device, comprising:
an integrated circuit chip having a chip input/output element;
a packaging component having a package input/output element;
two or more connection elements for connecting the chip input/output element with the package input/output element; and
a protective layer covering the integrated circuit chip, the two or more connection elements, and a portion of the packaging component such that the package input/output element is uncovered,
wherein the two or more connection elements are configured to provide a set input/output impedance at the package input/output element.

2. An integrated circuit device, as recited in claim 1, wherein the set input/output impedance is one of about 50 ohms and about 75 ohms.

3. An integrated circuit device, as recited in claim 1, wherein the integrated circuit chip includes a low noise amplifier circuit

4. An integrated circuit device, as recited in claim 1, wherein the packaging input/output element is one of: a packaging pad, a lead frame, and a solder ball.

5. (canceled)

6. (canceled)

7. (canceled)

8. (canceled)

9. An integrated circuit device, as recited in claim 1, wherein the integrated circuit device is an ultrawide bandwidth device.

10. An integrated circuit device, comprising:
an integrated circuit chip having a plurality of first clip input/output elements;
a packaging component having a plurality of package input/output elements;
a plurality of connection elements for connecting the chip input/output elements with the package input/output elements; and
a protective layer covering the integrated circuit chip, the plurality of connection elements, and a portion of the packaging such that the plurality of package input/output elements are uncovered,
wherein a first chip input/output element selected from the plurality of chip input/output elements is connected to a first package input/output element selected from the plurality of package input/output elements by a first group of connection elements selected from the plurality of connection elements,
wherein the first group of connection elements comprises two or more of the plurality of connection elements, and
wherein the first group of connection elements are configured to provide a set input/output impedance at the first package input/output element.

11. An integrated circuit device, as recited in claim 10, wherein the set input/output impedance is one of about 50 ohms and about 75 ohms.

12. An integrated circuit device, as recited in claim 10, wherein the integrated circuit chip includes a low noise amplifier circuit

13. An integrated circuit device, as recited in claim 10, wherein the plurality of packaging input/output elements comprise one of: a set of packaging pads a set of lead frames, and a ball grid array.

14. An integrated circuit device, as recited in claim 10, wherein the plurality of connection elements comprise one of: a plurality of wire bonds and a plurality of vias within an integrated circuit substrate.

15. An integrated circuit device, as recited in claim 10,
wherein a second chip input/output element selected from the plurality of chip input/output elements is connected to a second package input/output element selected from the plurality of package input/output elements by a second group of connection elements selected from the plurality of connection elements,
wherein the second group of connection elements comprises two or more of the plurality of connection elements, and
wherein the second group of connection elements are configured to provide the set input/output impedance at the second package input/output element.

16. An integrated circuit device, as recited in claim 10, wherein the packaging component comprises one of: plastic and ceramic.

17. An integrated circuit device, as recited in claim 10, wherein the first group of connection elements are configured to provide the set input/output impedance at the package input/output element over a bandwidth exceeding 2 GHz.

18. An integrated circuit device, as recited in claim 10, wherein the integrated circuit device is an ultrawide bandwidth device.

19. A method of matching the input/output impedance of an integrated circuit device, comprising:
attaching an integrated circuit chip having a chip input/output element to a packaging component having a package input/output element;
connecting the chip input/output element to the package input/output elements with two or more connection elements in parallel; and
covering the integrated circuit chip, the two or more connection elements, and a portion of the packaging with a protective material such that the package input/output element is uncovered,
wherein the two or more connection elements are configured to provide a set input/output impedance at the package input/output element.

20. A method of matching the input/output impedance of an integrated circuit device, as recited in claim 19, wherein the integrated circuit chip includes a low noise amplifier circuit.

21. A method of matching the input/output impedance of an integrated circuit device, as recited in claim 19, wherein the packaging input/output element is one of: a packaging pad, a lead frame, and a solder ball.

22. A method of matching the input/output impedance of an integrated circuit device, as recited in claim 19, wherein the two or more connection elements are each one of: a wire bond and a via within an integrated circuit substrate.

23. A method of matching the input/output impedance of an integrated circuit device, as recited in claim 19, wherein the two or more connection elements are configured to provide the set input/output impedance at the package input/output element over a bandwidth exceeding 2 GHz.

24. A method of matching the input/output impedance of an integrated circuit device, as recited in claim 19, wherein the method is implemented in an ultrawide bandwidth device.

25. An integrated circuit device, as recited in claim 19, wherein the set input/output impedance is one of about 50 ohms and about 75 ohms.

26. An integrated circuit device, as recited in claim 19, wherein the two or more connection elements are each one of a wire bond and a via within an integrated circuit substrate.

27. An integrated circuit device, as recited in claim 19, wherein the two or more connection elements comprise one of two connection elements and three connection elements.

28. An integrated circuit device, as recited in claim 19, wherein the packaging component comprises one of plastic and ceramic.
